(19) United States
(12) Patent Application Publication
(10) Pub. No.: US 2026/0311773 A1
(43) Pub. Date: Oct. 8, 2026

(54) APPARATUS AND OPERATION METHOD OF FLASH MEMORY

(71) Applicant: SEOUL NATIONAL UNIVERSITY R&DB FOUNDATION, Seoul (KR)

(72) Inventors: Jihong KIM, Seoul (KR); Jaeyong LEE, Seoul (KR)

(21) Appl. No.: 19/424,570

(22) Filed: Dec. 18, 2025

(30) Foreign Application Priority Data
Apr. 7, 2025 (KR) 10-2025-0044778
Aug. 27, 2025 (KR) 10-2025-0119763

(51) Int. Cl. G11C 16/26; G11C 16/08; G11C 16/10; G11C 16/24

(52) U.S. Cl. CPC G11C 16/26; G11C 16/08; G11C 16/10; G11C 16/24

(57) ABSTRACT

A flash memory device includes a memory cell array in which a plurality of memory cells are arranged, and a controller. The controller precharges a bitline and a wordline connected to the memory cell according to a first command, causes a target memory cell to perform a first operation, floats the bitline and the wordline for a threshold time, determines whether a second command is input within the threshold time, and controls whether to recharge or discharge the bitline and the wordline according to the second command. When the second command is input, the controller recharges the bitline and the wordline connected to the target memory cell, and when the second command is input after the threshold time has elapsed, the controller discharges the bitline and the wordline connected to the memory cell on which the second command is to be performed.

### CROSS-REFERENCE TO RELATED APPLICATION

This application is based on and claims priority under 35 U.S.C. §119 to Korean Patent Application No. 10-2025-0119763, filed on Aug. 27th, 2025, and Korean Patent Application No. 10-2025-0044778, filed on Apr. 7th, 2025, in the Korean Intellectual Property Office, the disclosure of which is incorporated by reference herein in its entirety.

### BACKGROUND

### Field

The present invention relates to a flash memory device and an operation method thereof.

Recently, in the field of flash memory, as data usage increases, the demand for storage devices that support high-capacity and high-performance read bandwidth has significantly increased.

FIG. 1 is a graph illustrating the block-by-block sequential access rate of mobile workloads during a read operation of a conventional flash memory. This indicates that as the amount of data continues to increase, the sequentiality of data read operations in flash memory also increases.

That is, the high sequential access rate of about 72.5% shown in the graph of FIG. 1 implies that, in workloads such as photos, videos, and games, the amount of data used has increased, but the maximum program/read unit has not increased proportionally. Therefore, read and write operations are repeatedly and continuously performed.

In this regard, FIGS. 2A to 2C illustrate a process of a conventional continuous read operation of flash memory. The continuous read operation of the flash memory can be largely divided into three stages.

First, as shown in FIG. 2A, after a read command is input, a precharge operation is performed to charge a target voltage level for the read operation.

Next, as shown in FIG. 2B, an evaluation operation is performed to sense and identify the data of a target cell.

FIG. 2C illustrates the final stage. In this stage, a discharge operation is performed. Also referred to as a recovery operation, this process initializes the wordline (WL) and bitline (BL), reads the data, and performs a dump process to output the data externally.

As described above, even during continuous read operations, a recovery operation is performed every time a read operation is completed. This refers to an operation that recovers the BL, WL, and pumps. Although a program operation differs in that it repeatedly performs the incremental step pulse program (ISPP) operation according to the target level difference, it basically includes three processes: precharge, program, and recovery.

In the present invention, a new operation method is proposed that can resolve the problem of the conventional technique in which a recovery operation is repeatedly performed for every read or program operation.

### Patent Documents

Korean Patent Publication No. 10-2314137 (Title: Nonvolatile Memory Device for Selectively Performing Recovery Operation and Operation Method Thereof)

### SUMMARY

In order to solve the above-described problems, the present invention is directed to proposing a technology that enables fast and power-efficient data processing by selectively performing charging and discharging of voltages required during continuous operations of a flash memory.

However, the technical problem to be achieved by the present embodiment is not limited to the above-mentioned problems, and other technical problems may also exist.

A flash memory device proposed in the present invention includes a plurality of memory cells; a memory cell array in which the plurality of memory cells are arranged; and a controller configured to control the memory cells. The controller precharges a bitline and a wordline connected to the memory cells according to an input of a first command, allows a target memory cell to perform a first operation according to the first command, floats the bitline and the wordline for a threshold time after the first operation, determines whether a second command is input within the threshold time after the first operation, and controls whether to recharge or discharge the bitline according to an input timing of the second command. When the second command is input within the threshold time, the controller recharges the bitline and the wordline connected to the memory cell on which the second command is to be performed. When the second command is input after the threshold time has elapsed, the controller discharges the bitline and the wordline connected to the memory cell on which the second command is to be performed.

In addition, an operation method of a flash memory device includes: precharging a bitline and a wordline connected to a target memory cell according to an input of a first command by a controller included in the device; allowing the target memory cell to perform a first operation according to the first command; floating the bitline and the wordline for a threshold time after the first operation; and determining whether a second command is input within the threshold time after the first operation and controlling whether to recharge or discharge the bitline and the wordline according to an input timing of the second command. When the second command is input within the threshold time, the method includes recharging the bitline and the wordline connected to the memory cell on which the second command is to be performed, and when the second command is input after the threshold time has elapsed, the method includes discharging the bitline and the wordline connected to the memory cell on which the second command is to be performed.

Furthermore, the flash memory device includes a plurality of memory cells; a memory cell array in which the plurality of memory cells are arranged; and a controller configured to control the plurality of memory cells. The controller precharges a bitline and a wordline connected to the memory cells according to an input of an incremental step pulse program (ISPP) command, allows a target memory cell to perform a first program operation corresponding to a first program voltage, discharges a wordline of the target memory cell only to a read voltage level after the first program operation, and performs a verification read operation while maintaining a pass voltage in wordlines of other memory cells. The controller then recharges the wordline voltage of the target memory cell to a second program voltage and performs a second program operation while maintaining the pass voltage in the other wordlines. After the second program operation, the controller discharges the wordline of the target memory cell only to the read voltage level and performs a verification read operation while maintaining the pass voltage in the other wordlines.

In addition, an operation method of a flash memory device includes: precharging a bitline and a wordline connected to the memory cells according to an input of an ISPP command; performing a first program operation corresponding to a first program voltage on a target memory cell; after the first program operation, discharging a wordline of the target memory cell only to a read voltage level and performing a verification read operation while maintaining a pass voltage in wordlines of other memory cells; recharging the wordline voltage of the target memory cell to a second program voltage and performing a second program operation while maintaining the pass voltage in the other wordlines; and, after the second program operation, discharging the wordline of the target memory cell only to the read voltage level and performing a verification read operation while maintaining the pass voltage in the other wordlines.

According to the present invention, by reusing the charged voltage in a flash memory, the performance and power efficiency of operations can be improved, thereby enhancing the performance of NAND flash–based high-density storage devices.

In particular, through a delayed discharge configuration that intentionally delays the discharge stage accompanying read or write operations in the flash memory, the invention enables fast and efficient operation by reusing the previously charged voltage.

### BRIEF DESCRIPTION OF THE DRAWINGS

FIG. 1 is a graph illustrating the sequential access rate per block of mobile workloads in a conventional flash memory technology.

FIG. 2 illustrates a read operation process of a conventional flash memory technology.

FIG. 3 illustrates a configuration of a flash memory device according to an embodiment of the present invention.

FIG. 4 illustrates an operation sequence of a conventional flash memory device and the device proposed in the present invention.

FIG. 5 is a flowchart illustrating an operation method of a flash memory device according to an embodiment of the present invention.

FIG. 6 illustrates a principle of a read operation of a device according to an embodiment of the present invention.

FIG. 7 is a graph illustrating a leakage voltage value of a wordline according to a tINTERVAL time of the flash memory.

FIG. 8 illustrates read operation sequences in two cases of flash memory operations according to an embodiment of the present invention.

FIG. 9 includes graphs comparing wordline voltages between the conventional flash memory technology and the technology proposed in the present invention.

FIG. 10 illustrates voltages applied to wordlines in a time sequence according to an embodiment of the present invention.

FIG. 11 includes graphs comparing wordline voltages during charging and discharging between the conventional flash memory technology and the technology proposed in the present invention.

FIG. 12 is a flowchart illustrating an operation method of a flash memory device according to an embodiment of the present invention.

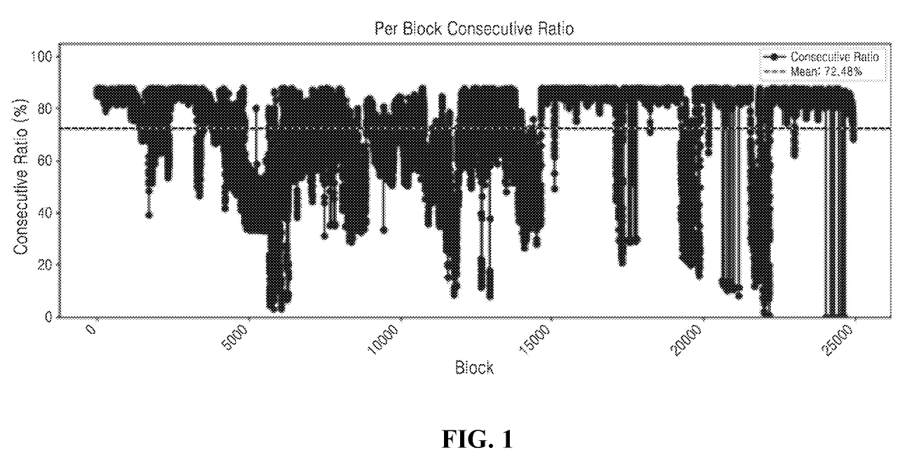

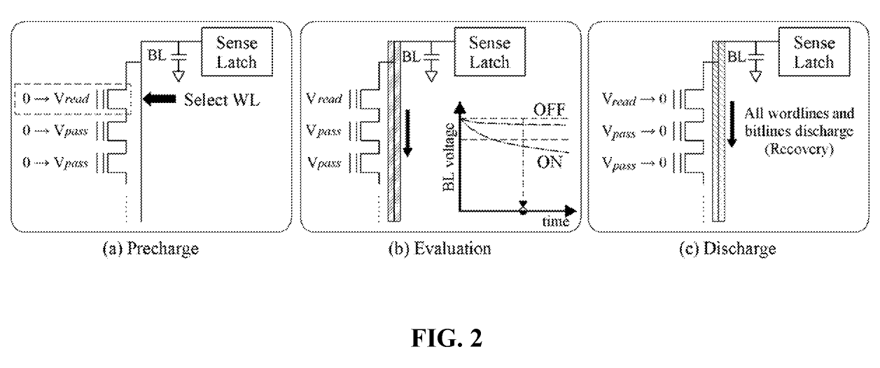

### DETAILED DESCRIPTION

Hereinafter, embodiments of the present invention will be described in detail with reference to the accompanying drawings so that those skilled in the art can easily carry out the invention. However, the present invention may be implemented in various different forms and is not limited to the embodiments described herein. Parts irrelevant to the explanation are omitted in order to clearly describe the present invention in the drawings, and like reference numerals are assigned to like elements throughout the specification.

In the entire specification, when a part is referred to as being “connected” to another part, it includes not only a case where they are “directly connected” but also a case where they are “electrically connected” with other elements interposed therebetween. In addition, when a part is referred to as “including” certain elements, it means that other elements are not excluded unless otherwise specified, and that other elements may further be included.

In this specification, the term “unit” refers to a unit implemented by hardware, a unit implemented by software, or a unit implemented using both hardware and software. A single unit may be implemented by using two or more hardware elements, or two or more units may be implemented by a single hardware element. The term “unit” is not limited to software or hardware but may be configured to exist in an addressable storage medium or to execute one or more processors. Therefore, by way of example, a “unit” may include components such as software components, object-oriented software components, class components, and task components, as well as processes, functions, attributes, procedures, subroutines, segments of program code, drivers, firmware, microcode, circuits, data, databases, data structures, tables, arrays, and variables. The functions provided within components or units may be combined into a smaller number of components or units or may be further divided into additional components or units. Furthermore, the components or units may be implemented so as to execute one or more CPUs within a device.

Hereinafter, the embodiments of the present invention will be described in detail with reference to the accompanying drawings.

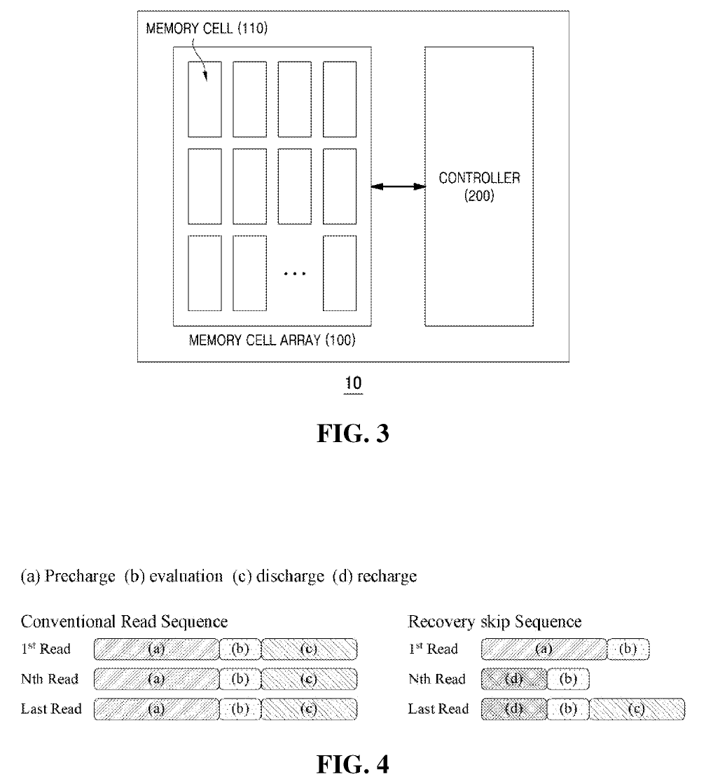

FIG. 3 illustrates a configuration of a device (10) proposed in the present invention. The flash memory device (10) proposed herein includes a plurality of memory cells (110), a memory cell array (100) in which the plurality of memory cells (110) are arranged, and a controller (200) configured to control the plurality of memory cells (110).

The controller (200) efficiently operates the device (10) by selectively performing recharging or discharging of a bitline (120) and a wordline (130) associated with a corresponding operation according to the input timing of a command instructing each of the continuous operations performed by the flash memory device (10).

Specifically, the controller (200) precharges the bitline (120) and the wordline (130) connected to the memory cell (110) according to an input of a first command, allows a target memory cell (110) to perform a first operation according to the first command, floats the bitline (120) and the wordline (130) for a threshold time after performing the first operation, determines whether a second command is input within the threshold time after the first operation, and controls whether to recharge or discharge the bitline (120) and the wordline (130) according to an input timing of the second command. When the second command is input within the threshold time, the controller (200) recharges the bitline (120) connected to the target memory cell (110) on which the second command is to be performed. When the second command is input after the threshold time has elapsed, the controller (200) discharges the bitline (120) and the wordline (130) connected to the target memory cell (110) on which the second command is to be performed.

In addition, when the first command is a read command, the controller (200) applies a high-level voltage to the bitline (120), applies a read voltage to a wordline (130) connected to a memory cell (110) that is a target of the read operation among a plurality of wordlines (130) connected to the bitline (120), and applies a pass voltage to wordlines (130) connected to the remaining memory cells (110). Moreover, when the first command is a program command, the controller (200) applies a high-level voltage to the bitline (120), applies a program voltage to a wordline (130) connected to a memory cell (110) that is a target of the write operation among a plurality of wordlines (130) connected to the bitline (120), and applies a pass voltage to the wordlines (130) connected to the remaining memory cells (110).

When the second command is input within the threshold time, the controller (200), if the second command is a read command, applies a high-level voltage to the bitline (120), applies a read voltage to a wordline (130) connected to a memory cell (110) that is the target of the read operation among a plurality of wordlines (130) connected to the bitline (120), and applies a pass voltage to wordlines (130) connected to the remaining memory cells (110). In addition, when the second command is a program command, the controller (200) applies a high-level voltage to the bitline (120), applies a program voltage to a wordline (130) connected to a memory cell (110) that is the target of the write operation among a plurality of wordlines (130) connected to the bitline (120), and applies a pass voltage to wordlines (130) connected to the remaining memory cells (110).

FIG. 4 compares the configuration of a read operation sequence of a conventional flash memory with that of a read operation sequence of the flash memory proposed in the present invention.

In the conventional read operation sequence, the first read operation (1st Read), the Nth read operation (Nth Read), and the last read operation (Last Read) of a flash memory all include the same three stages of (a) precharge, (b) evaluation, and (c) discharge. In contrast, in the recovery-skip sequence proposed by the present invention, the flash memory omits the discharge operation in the first read operation, performs a recharge operation (d) during the Nth read operation, and performs the discharge operation (c) only in the last read operation.

That is, in the conventional technology, a discharge stage is uniformly performed after each read operation, whereas in the present invention, a concept of delayed discharge is applied, in which the discharge is intentionally delayed depending on the memory cell (110).

Next, the operation process of the device (10) in each stage of the recovery-skip sequence described above will be explained in detail.

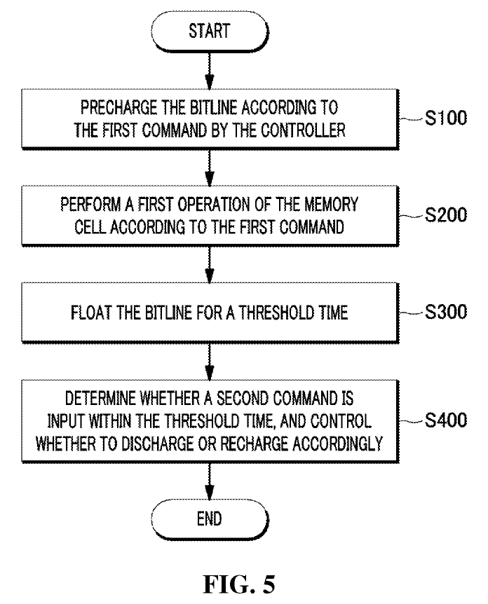

FIG. 5 is a flowchart illustrating an operation method of the flash memory device (10) proposed in the present invention.

The operation method of the flash memory device (10) includes the following steps: the controller (200) included in the device (10) precharges (S100) a bitline (120) and a wordline (130) connected to a target memory cell (110) according to an input of a first command; the target memory cell (110) performs (S200) a first operation according to the first command; after performing the first operation, the controller floats (S300) the bitline (120) and the wordline (130) for a threshold time; and determines (S400) whether a second command is input within the threshold time after the first operation and controls whether to recharge or discharge the bitline (120) and the wordline (130) according to the input timing of the second command. In step S400, when the second command is input within the threshold time, the controller recharges the bitline (120) and the wordline (130) connected to the memory cell (110) on which the second command is to be performed. When the second command is input after the threshold time has elapsed, the controller discharges the bitline (120) and the wordline (130) connected to the memory cell (110) on which the second command is to be performed.

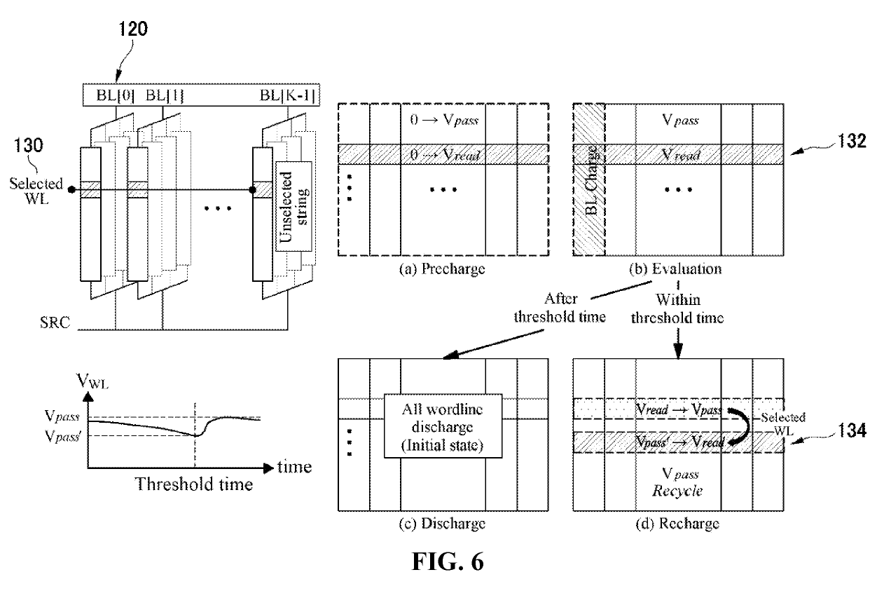

FIGS. 6 to 9 illustrate detailed configurations of the device (10) proposed in the present invention and detailed operation processes performed in each stage.

First, in step S100, the controller (200) precharges the bitline (120) connected to the target memory cell (110) according to an input of the first command. Each bitline (120), illustrated as BL[0] to BL[K–1] in FIG. 6, is connected to column-based memory cells (110) including a plurality of memory cells, and in this step, each bitline (120) is precharged to a high level (a).

For example, when the first command is a read command, while applying a high-level voltage to each bitline (120), the controller (200) applies a read voltage (Vread) to a selected wordline (Selected WL) (130) connected to a memory cell (110) that is the target of the read operation among a plurality of wordlines (130) connected to the bitline (120), and applies a pass voltage (Vpass) to wordlines (130) connected to the remaining memory cells (110). The pass voltage turns on the non-target memory cells (110) to allow current to flow.

Similarly, when the first command is a program command, while applying a high-level voltage to the bitline (120), the controller (200) applies a program voltage to a wordline (130) connected to a memory cell (110) that is the target of the write operation among a plurality of wordlines (130) connected to the bitline (120), and applies a pass voltage to wordlines (130) connected to the remaining memory cells (110).

Next, in step S200, the controller (200) allows the target memory cell (110) to perform a first operation according to the first command.

In this step, an evaluation (b) operation for evaluating data is performed through the voltage applied to the wordline (120) in step S100 described above. Referring to the example of the read operation illustrated in (b) of FIG. 6, the first read operation is performed on the memory cell (110) connected to a first wordline (132), which is a wordline (130) connected to the target memory cell (110) of the first operation. Similarly, when the first command is a program operation, a verification operation may be additionally performed to read the state of the memory cell (110) according to the application of the program voltage.

In step S300, after performing the first operation of the target memory cell (110), the controller (200) floats the bitline (120) and the wordline (130) for a threshold time.

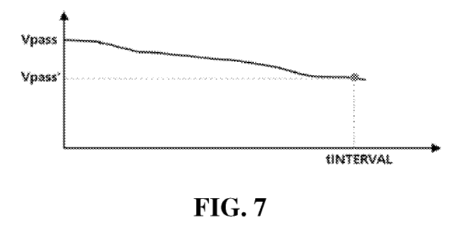

In this step, after performing the first operation in step S200, the controller determines whether the input timing of the command for the next operation (the second operation) occurs after the threshold time. During this time, as shown in FIG. 7, the voltage of the wordline (130) gradually decreases from Vpass to Vpass′. At this time, in order to delay the discharge while maintaining the residual voltage of the wordline (130), the controller floats the voltages of the bitline (120) and the wordline (130).

The final step, S400, involves determining whether the second command is input within the threshold time after the first operation of the target memory cell (110), and controlling whether to recharge or discharge the bitline (120) and the wordline (130) according to the input timing of the second command.

In this step, the operation is divided into two cases: when the second command is input within the threshold time, and when the second command is input after the threshold time has elapsed. The controller performs either recharging or discharging of the bitline (120) and the wordline (130) accordingly.

First, when the second command is input within the threshold time, the bitline (120) and the wordline (130) connected to the target memory cell (110) on which the second command is to be performed are recharged (d).

That is, when the second command is a read command, while applying a high-level voltage to the bitline (120), the controller applies a read voltage (Vread) to a second read wordline (134), which is a wordline (130) connected to the memory cell (110) that is the target of the read operation among a plurality of wordlines (130) connected to the bitline (120), and applies a pass voltage (Vpass) to the wordlines (130) connected to the remaining memory cells (110).

Similarly, when the second command is a program command, while applying a high-level voltage to the bitline (120), the controller applies a program voltage to a wordline (130) connected to the memory cell (110) that is the target of the write operation among a plurality of wordlines (130) connected to the bitline (120), and applies a pass voltage to the wordlines (130) connected to the remaining memory cells (110).

At this time, the time required for the voltage recharging stage may be set to increase in proportion to the threshold time.

Conversely, when the second command is input after the threshold time has elapsed, the controller (200) discharges (c) the bitline (120) and the wordline (130) connected to the target memory cell (110) on which the second command is to be performed.

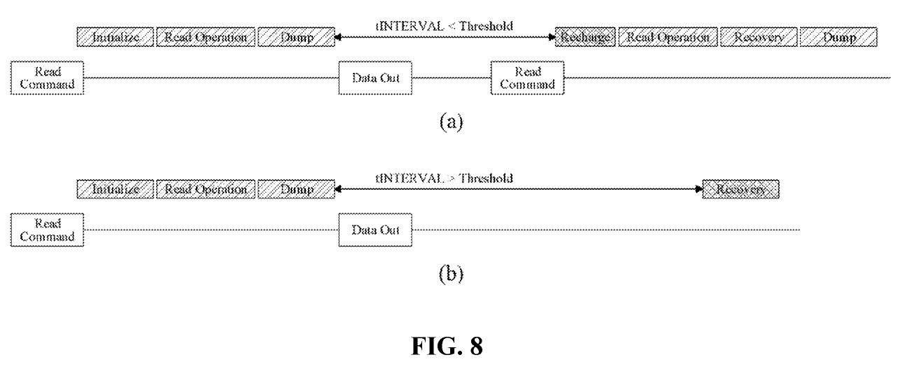

FIGS. 8A and 8B are operation diagrams illustrating a comparison of the device (10) between the two cases described above.

In both cases, the operation proceeds identically up to the dump stage of the first operation. As shown in FIG. 8A, when the second command is input within the threshold time (tINTERVAL < Threshold), a recharge operation is performed followed by the second operation. In contrast, as shown in FIG. 8B, when the second command is input after the threshold time (tINTERVAL > Threshold), a recovery operation is immediately performed after the dump stage of the first operation, and the voltage is discharged.

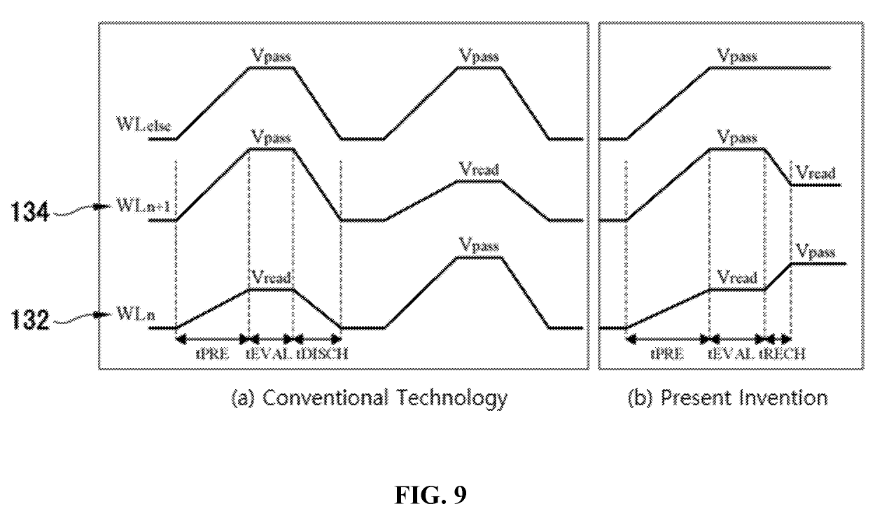

Furthermore, FIGS. 9A and 9B are graphs comparing the voltages of the wordlines (130) according to the operation sequences of the conventional flash memory and the flash memory device (10) proposed in the present invention.

First, as shown in FIG. 9A, in the read operation sequence of a conventional flash memory, all wordlines (WLn, WLn+1, and WLelse) repeatedly perform the same stages of precharge (tPRE), evaluation (tEVAL), and discharge (tDISCH), and the voltages are charged or discharged to Vpass or Vread accordingly.

However, as shown in FIG. 9B, in the operation method of the device (10) proposed in the present invention, during the precharge period (tPRE) of the bitline (120) according to the input command, a wordline (130) performing the read operation, such as WLn, is precharged to Vread, while the remaining wordlines (130) are precharged to Vpass.

That is, in step S100, when a read command is input as the first command for the memory cell (110) connected to the first wordline (132), the bitline (120) connected to the corresponding memory cell (110) is precharged. In this state, the controller (200) applies a high-level voltage to the bitline (120), applies a read voltage to the first wordline (132), and applies a pass voltage to the remaining wordlines (130), including the adjacent second wordline (134).

In addition, during the tEVAL period shown in FIG. 9, the read operation is performed, indicating that the read operation is performed on the memory cell connected to the first wordline (132) in step S200.

Finally, during the tRECH period, the second wordline (134), which performs the read operation according to the second command among the wordlines (130), undergoes a recharge operation, while a pass voltage is applied to the remaining wordlines (130).

This corresponds to step S400, in which, when a read command is input as the second command within the threshold time for the memory cell (110) connected to the second wordline (134) adjacent to the first wordline (132), a recharge operation is performed. In this state, the controller (200) applies a high-level voltage to the bitline (120), applies a read voltage to the second wordline (134), and applies a pass voltage to the remaining wordlines (130), including the first wordline (132).

In addition, the flash memory device (10) may apply the concept of delayed discharge proposed by the present invention even during execution of an incremental step pulse program (ISPP) command. More specifically, according to the input of an ISPP command, the flash memory device (10) precharges the bitline (120) and the wordline (130) connected to the memory cell (110), allows the target memory cell (110) to perform a first program operation corresponding to a first program voltage, discharges the wordline (130) of the target memory cell (110) only to a read voltage level after performing the first program operation, and performs a verification read operation while maintaining a pass voltage in the wordlines (130) of the remaining memory cells (110). The device then recharges the wordline voltage of the target memory cell (110) to a second program voltage, performs a second program operation while maintaining the pass voltage in the other wordlines (130), and after performing the second program operation, discharges the wordline (130) of the target memory cell (110) only to the read voltage level while performing a verification read operation with the pass voltage maintained in the remaining wordlines (130).

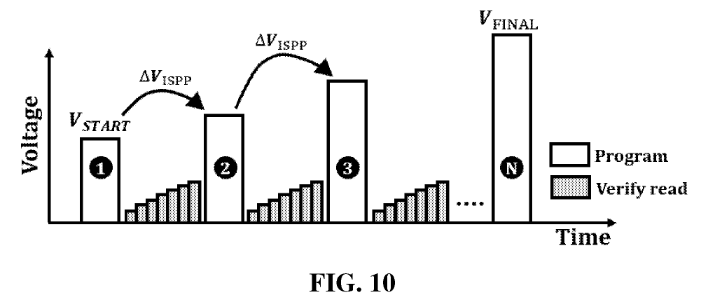

In this regard, FIG. 10 is a graph illustrating an example of voltages applied over time to the wordlines (130) when the memory cell (110) of the flash memory device (10) operates in the ISPP mode according to an embodiment of the present invention.

As shown in FIG. 10, according to the input of the incremental step pulse programming (ISPP) command, the memory cell (110) precharges the bitline (120) and the wordline (130) connected thereto, and performs a first program operation corresponding to a first program voltage on the target memory cell (110).

In this ISPP programming operation, a relatively low-level program voltage is first applied to the wordline (130), and the program voltage is gradually increased step by step.

Referring again to FIG. 10, a single operation of the memory cell (110) consists of a program operation in which the program voltage is applied to the wordline (130), and a verification read operation (verify read) for confirming whether the program operation has been properly performed.

That is, when the above operation is performed according to the input ISPP command, a program operation is performed after applying an initial voltage Vstart, and then, through a verification read operation, it is determined whether an additional voltage should be applied.

If an additional voltage is required, the program and verification operations are repeated after increasing the voltage by ΔVispp. In other words, the voltage is gradually increased by ΔVispp and the above operations are repeated from step 1 to N until programming of the memory cell (110) is completed.

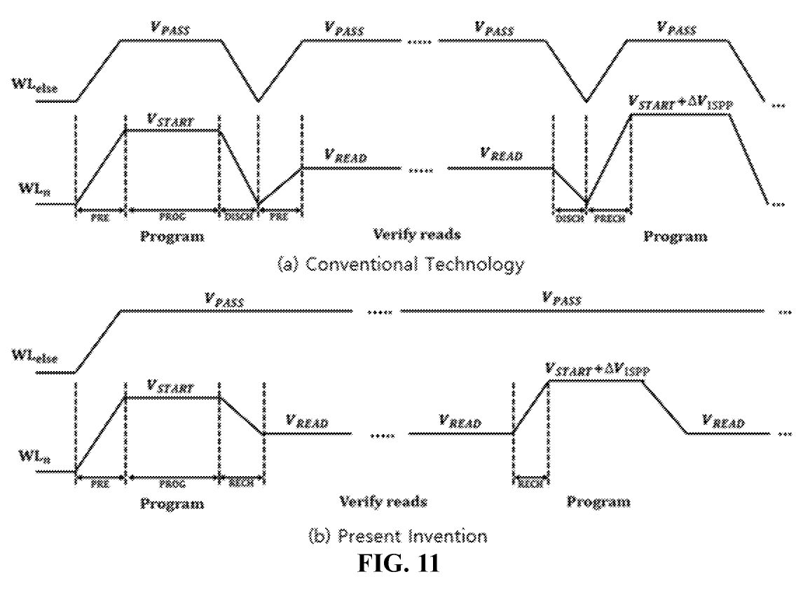

Meanwhile, FIGS. 11A and 11B are graphs comparing the voltages of the wordlines (130) during charging and discharging between the conventional flash memory technology and the technology proposed in the present invention.

First, as shown in FIG. 11A, in the conventional charge and discharge method, when transitioning from the program operation stage to the verification read stage and again from the verification read stage back to the program operation stage, all wordlines (130) (WLn, WLelse) are completely discharged to the initial state and then recharged to the target voltage (VREAD or Vpass) as shown in the graph.

However, as shown in FIG. 11B, in the method proposed by the present invention, when transitioning from the program operation stage to the verification read stage, the voltage (WLn) of the wordline (130) on which the program operation is performed is discharged only to the target level (VREAD), while the voltages of the remaining wordlines (130) (WLelse) are maintained at Vpass.

Conversely, when transitioning from the verification read operation to the next program operation stage, the voltage of the wordline (WLn) (130) on which the program operation is performed is recharged (RECH) to the target level (Vstart + ΔVispp), while the voltages of the other wordlines (WLelse) (130) are maintained at Vpass.

That is, the flash memory device (10) proposed in the present invention differs from the conventional technology shown in FIG. 11A in that, after performing the first program operation, the wordline (130) of the target memory cell (110) is discharged only to the read voltage level (VREAD), and the wordlines (130) of the remaining memory cells (110) maintain the pass voltage (VPASS) while performing a verification read operation.

Subsequently, the device (10) recharges the wordline (130) voltage of the target memory cell (110) to the second program voltage (VSTART + ΔVPASS), performs a second program operation while maintaining the pass voltage (VPASS) in the remaining wordlines (130), and after performing the second program operation, discharges the wordline (130) of the target memory cell (110) only to the read voltage level (VREAD) while maintaining the pass voltage (VPASS) in the remaining wordlines (130) during the verification read operation.

The detailed process of the operation of the flash memory device (10) by the ISPP command described above is as follows.

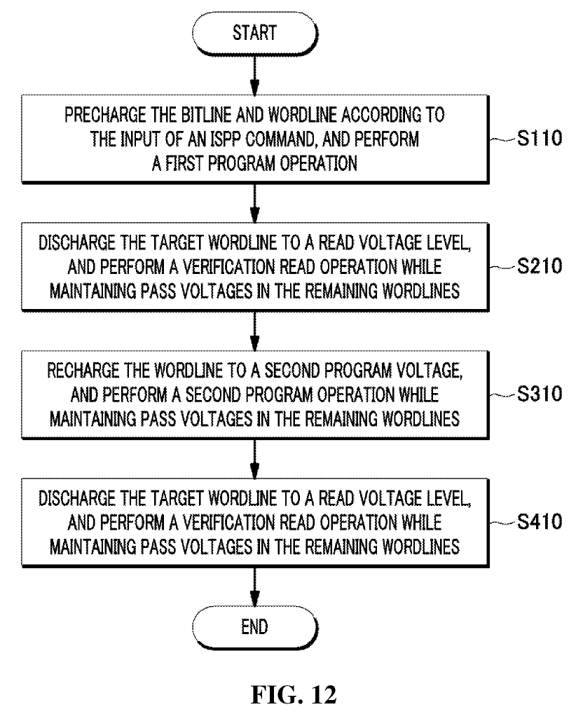

FIG. 12 is a flowchart illustrating a process in which the flash memory device (10) operates by an ISPP command.

The operation method of the flash memory device (10) includes: precharging a bitline (120) and a wordline (130) connected to a memory cell (110) according to an input of an ISPP command, and performing a first program operation on the target memory cell (110) corresponding to a first program voltage (S110); after performing the first program operation, discharging the wordline (130) of the target memory cell (110) only to the read voltage level, and performing a verification read operation while maintaining the pass voltage in the wordlines (130) of the remaining memory cells (110) (S210); recharging the wordline voltage of the target memory cell (110) to a second program voltage and performing a second program operation while maintaining the pass voltage in the remaining wordlines (130) (S310); and after performing the second program operation, discharging the wordline (130) of the target memory cell (110) only to the read voltage level, and performing a verification read operation while maintaining the pass voltage in the remaining wordlines (130) (S410).

The detailed operation of each step is as follows.

First, in step S110, a bitline (120) and a wordline (130) connected to the memory cell (110) are precharged according to the input of an ISPP command, and the target memory cell (110) performs a first program operation corresponding to a first program voltage.

In this step, the controller (200) precharges the bitline (120) and the wordline (130) connected to the target memory cell (110) according to the input of the ISPP command, and the target memory cell (110) performs the first program operation according to the ISPP command.

Next, in step S210, after performing the first program operation in step S110, the wordline (130) of the target memory cell (110) is discharged only to the read voltage level, and the wordlines (130) of the remaining memory cells (110) maintain the pass voltage while performing the verification read operation.

Specifically, the voltage of the wordline (130) connected to the memory cell (110) that is the target of the first program operation is discharged to the read voltage level, and the remaining wordlines (130) that are not subjected to the first program operation are maintained at the pass voltage.

In this state, with the above voltages applied, the wordlines (130) perform the verification read operation.

Next, in step S310, the wordline voltage of the target memory cell (110) is recharged to the second program voltage, and the wordline voltages of the remaining memory cells are maintained at the pass voltage while performing the second program operation.

In this step, the voltage of the wordline (130) connected to the memory cell (110) that is the target of the second program operation is recharged to the second program voltage, and the remaining wordlines (130) that are not the target of the second program operation are maintained at the pass voltage.

With the voltages applied as described above, the wordline (130) charged to the second program voltage performs the second program operation.

Finally, in step S410, after performing the second program operation, the wordline (130) of the target memory cell (110) is discharged only to the read voltage level, and the wordlines (130) of the remaining memory cells (110) maintain the pass voltage while performing the verification read operation.

In this step, when the second program operation ends in step S310, the voltage of the wordline (130) connected to the memory cell (110) that is the target of the second program operation is discharged to the read voltage level, and the wordlines (130) that are not subjected to the second program operation maintain the pass voltage.

Then, in the state where the above voltages are applied, the wordlines (130) perform the verification read operation.

The foregoing description of the present invention is merely illustrative, and it will be understood by those skilled in the art that various modifications, additions, and substitutions can be made without departing from the spirit or essential characteristics of the invention. Therefore, the embodiments described above should be understood as exemplary rather than limiting in all respects. For example, each component described as being implemented as a single entity may also be implemented in a distributed manner, and likewise, components described as being distributed may also be implemented in a combined form.

The scope of the present invention is defined by the claims described below, rather than by the foregoing detailed description, and all modifications or variations derived from the meaning and scope of the claims and their equivalents should be interpreted as being included within the scope of the present invention.

### DESCRIPTION OF REFERENCE NUMERALS

10: Device

100: Memory cell array

110: Memory cell

120: Bitline

130: Wordline

200: Controller

What is claimed is:

1. A flash memory device comprising:
a plurality of memory cells;
a memory cell array in which the plurality of memory cells are arranged; and
a controller configured to control the plurality of memory cells,
wherein the controller is configured to:
precharge a bitline and a wordline connected to the memory cell according to an input of a first command; cause a target memory cell to perform a first operation corresponding to the first command; float the bitline and the wordline for a threshold time after performing the first operation; determine whether a second command is input within the threshold time after performing the first operation; control whether to recharge or discharge the bitline and the wordline according to an input timing of the second command;
recharge the bitline and the wordline connected to the target memory cell on which the second command is to be performed when the second command is input within the threshold time;
and discharge the bitline and the wordline connected to the target memory cell on which the second command is to be performed when the second command is input after the threshold time has elapsed.

2. The flash memory device according to claim 1,
wherein the controller is configured to,
when the first command is a read command, apply a high-level voltage to the bitline, apply a read voltage to a wordline connected to a read target memory cell among a plurality of wordlines connected to the bitline, and apply a pass voltage to wordlines connected to remaining memory cells; and
when the first command is a program command, apply a high-level voltage to the bitline, apply a program voltage to a wordline connected to a write target memory cell among the plurality of wordlines connected to the bitline, and apply a pass voltage to wordlines connected to remaining memory cells.

3. The flash memory device according to claim 1,
wherein the controller is configured to,
when the second command is input within the threshold time,
apply a high-level voltage to the bitline,
when the second command is a read command, apply a read voltage to a wordline connected to a read target memory cell among a plurality of wordlines connected to the bitline, and apply a pass voltage to wordlines connected to remaining memory cells; and
when the second command is a program command, apply a program voltage to a wordline connected to a write target memory cell among the plurality of wordlines connected to the bitline, and apply a pass voltage to wordlines connected to remaining memory cells.

4. A method of operating a flash memory device, the method comprising:
(a) precharging, by a controller included in the device, a bitline and a wordline connected to a target memory cell according to an input of a first command;
(b) performing, by the target memory cell, a first operation corresponding to the first command;
(c) floating the bitline and the wordline for a threshold time after performing the first operation; and
(d) determining whether a second command is input within the threshold time after performing the first operation, and controlling whether to recharge or discharge the bitline and the wordline according to an input timing of the second command,
wherein step (d) comprises:
recharging the bitline and the wordline connected to the target memory cell on which the second command is to be performed when the second command is input within the threshold time; and
discharging the bitline and the wordline connected to the target memory cell on which the second command is to be performed when the second command is input after the threshold time has elapsed.

5. The method of operating a flash memory device according to claim 4,
wherein step (a) comprises:
when the first command is a read command, applying a high-level voltage to the bitline, applying a read voltage to a wordline connected to a read target memory cell among a plurality of wordlines connected to the bitline, and applying a pass voltage to wordlines connected to remaining memory cells; and
when the first command is a program command, applying a high-level voltage to the bitline, applying a program voltage to a wordline connected to a write target memory cell among the plurality of wordlines connected to the bitline, and applying a pass voltage to wordlines connected to remaining memory cells.

6. The method of operating a flash memory device according to claim 4,
wherein, in step (d), the recharging step comprises:
when the second command is a read command, applying a high-level voltage to the bitline, applying a read voltage to a wordline connected to a read target memory cell among a plurality of wordlines connected to the bitline, and applying a pass voltage to wordlines connected to remaining memory cells; and
when the second command is a program command, applying a high-level voltage to the bitline, applying a program voltage to a wordline connected to a write target memory cell among the plurality of wordlines connected to the bitline, and applying a pass voltage to wordlines connected to remaining memory cells.

7. The method of operating a flash memory device according to claim 4,
wherein a time required for the recharging step performed in step (d) is set to increase in proportion to the threshold time.

8. The method of operating a flash memory device according to claim 4,
wherein in step (a), when a read command as the first command is input for a memory cell connected to a first wordline, a bitline connected to the memory cell is precharged, and in a state where a high-level voltage is applied to the bitline, a read voltage is applied to the first wordline, and a pass voltage is applied to remaining wordlines including a second wordline adjacent to the first wordline;
in step (b), a read operation is performed for the memory cell connected to the first wordline; and
in step (d), when a read command as the second command is input for a memory cell connected to the second wordline adjacent to the first wordline within the threshold time, a recharge operation is performed by applying a high-level voltage to the bitline, applying a read voltage to the second wordline, and applying a pass voltage to remaining wordlines including the first wordline.

9. A flash memory device comprising:
a plurality of memory cells;
a memory cell array in which the plurality of memory cells are arranged; and
a controller configured to control the plurality of memory cells,
wherein the controller is configured to:
precharge a bitline and a wordline connected to the memory cell according to an input of an ISPP (Incremental Step Pulse Programming) command, and cause a target memory cell to perform a first program operation according to a first program voltage;
after performing the first program operation, discharge a wordline of the target memory cell only to a read voltage level, and perform a verification read operation while maintaining pass voltages in wordlines of remaining memory cells;
recharge the wordline voltage of the target memory cell to a second program voltage and perform a second program operation while maintaining pass voltages in remaining wordlines; and
after performing the second program operation, discharge the wordline of the target memory cell only to the read voltage level, and perform a verification read operation while maintaining pass voltages in the wordlines of remaining memory cells.

10. A method of operating a flash memory device, the method comprising:
(a) precharging a bitline and a wordline connected to a memory cell according to an input of an ISPP (Incremental Step Pulse Programming) command, and performing a first program operation for a target memory cell according to a first program voltage;
(b) after performing the first program operation, discharging a wordline of the target memory cell only to a read voltage level, and performing a verification read operation while maintaining pass voltages in wordlines of remaining memory cells;
(c) recharging the wordline voltage of the target memory cell to a second program voltage, and performing a second program operation while maintaining pass voltages in remaining wordlines; and
(d) after performing the second program operation, discharging the wordline of the target memory cell only to the read voltage level, and performing a verification read operation while maintaining pass voltages in wordlines of remaining memory cells.
